(19) United States
(12) Patent Application Publication
(10) Pub. No.: US 2013/0299829 A1
(43) Pub. Date: Nov. 14, 2013

(54) PHOTOELECTRIC CONVERSION DEVICE

(71) Applicant: Shinya Ishikawa, Higashiomi-shi (JP)

(72) Inventor: Shinya Ishikawa, Higashiomi-shi (JP)

(73) Assignee: KYOCERA CORPORATION, Kyoto-shi, Kyoto (JP)

(21) Appl. No.: 13/997,187

(22) PCT Filed: Dec. 21, 2011
(86) PCT No.: PCT/JP2011/079676

§ 371 Date: Jun. 21, 2013

(30) Foreign Application Priority Data
Dec. 22, 2010 (JP) 2010-286274
May 25, 2011 (JP) 2011-117090

(51) Int. Cl. H01L 31/0376

(52) U.S. Cl. CPC H01L 31/0376
USPC 257/53

(57) ABSTRACT

A photoelectric conversion device is disclosed. The photoelectric conversion device includes an electrode layer, an intermediate layer on the electrode layer and a light-absorbing layer on the intermediate layer. The electrode layer includes molybdenum. The light-absorbing layer includes one or more Group I-B elements, one or more Group III-B elements, and at least one element of sulfur and selenium. The intermediate layer includes an amorphous layer. The amorphous layer includes at least one of the sulfur and the selenium which are contained in the light-absorbing layer, and the molybdenum.

### TECHNICAL FIELD

The present invention relates to a photoelectric conversion device.

### BACKGROUND ART

In a chalcopyrite-based photoelectric conversion device, usually soda-lime glass is used for a substrate, and formed thereon is a molybdenum thin-film serving as a lower electrode (hereinafter referred to as “electrode layer”). On the electrode layer, a light-absorbing layer is provided with a chalcogen compound semiconductor layer (chalcopyrite-based semiconductor layer) made of copper indium gallium diselenide (CIGS) or the like. Japanese Unexamined Patent Application Publication No. 2002-319686 discloses that a molybdenum selenide (MoSe₂) layer is formed at the interface between the electrode layer and the light-absorbing layer.

### SUMMARY OF INVENTION

However, when a plurality of such MoSe₂ layers are formed in such a state that a c-axis is perpendicular to a surface of the electrode layer, the adhesion strength between the MoSe₂ layers is likely to be low. This causes the delamination of the MoSe₂ layers; hence, the light-absorbing layer is delaminated from the electrode layer in some cases.

An object of the present invention is to provide a photoelectric conversion device which reduces the delamination of a light-absorbing layer from an electrode layer and which has high reliability.

A photoelectric conversion device according to an embodiment of the present invention includes an electrode layer containing molybdenum; an intermediate layer provided on the electrode layer; and a light-absorbing layer which is provided on the intermediate layer and which contains a Group I-B element, a Group III-B element, and at least one of sulfur and selenium. The intermediate layer includes an amorphous layer containing the molybdenum and at least one of the sulfur and the selenium which are contained in the light-absorbing layer.

According to an embodiment of the present invention, an intermediate layer includes an amorphous layer containing molybdenum and at least one of sulfur and selenium which are contained in a light-absorbing layer, thereby making it possible to reduce occurrence of the delamination of an electrode layer from the light-absorbing layer.

### BRIEF DESCRIPTION OF DRAWINGS

FIG. 1 is a perspective view of an exemplary photoelectric conversion device according to an embodiment of the present invention.

FIG. 2 is a cross-sectional view of the photoelectric conversion device shown in FIG. 1.

FIGS. 3(a) to 3(f) are cross-sectional views illustrating an exemplary method for manufacturing a photoelectric conversion device according to the present invention.

### DESCRIPTION OF EMBODIMENTS

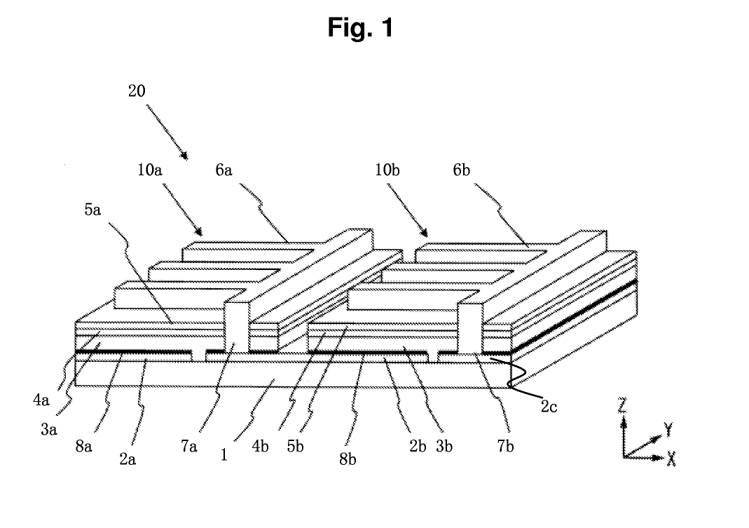

A photoelectric conversion device according to an embodiment of the present invention is described with reference to drawings. The drawings include one equipped with a right-handed XYZ-coordinate in which the X-axis lies in an arrangement direction (horizontal direction in FIG. 1) of photoelectric conversion cells 10.

The photoelectric conversion device 20 according to an embodiment of the present invention is formed by arranging a plurality of photoelectric conversion cells 10, as shown in FIG. 1. Each photoelectric conversion cell 10 includes a substrate 1, a plurality of electrode layers (hereinafter referred to as the lower electrode layers 2), a light-absorbing layer 3 corresponding to a first semiconductor layer, a buffer layer 4 corresponding to a second semiconductor layer, an upper electrode layer 5, current-collecting electrodes 6, and a connection conductor 7.

In the present embodiment, a photoelectric conversion layer contributing to photoelectric conversion shows an example thereof including the light-absorbing layer 3 and the buffer layer 4 hetero-joined thereto, and is not restricted to this. The photoelectric conversion layer may be one including homo-joined semiconductor layers having different conductivity type from each other.

A photoelectric conversion cell 10 is electrically coupled to a neighboring photoelectric conversion cell 10 through the connection conductor 7, which is provided so as to extend through the light-absorbing layers 3 and the buffer layers 4. In this embodiment, the connection conductor 7 electrically connects the upper electrode layer 5 of a photoelectric conversion cell 10 to the lower electrode layer 2 of another photoelectric conversion cell 10. This allows the neighboring photoelectric conversion cells 10 to be connected to each other in series along an X-direction in FIG. 1. Note that in a photoelectric conversion cell 10, photoelectric conversion is carried out by the light-absorbing layer 3 and the buffer layer 4, which are interposed between the upper electrode layer 5 and the lower electrode layer 2.

Members that the photoelectric conversion device 20 includes are described below. The substrate 1 is one for supporting the light-absorbing layers 3 and the like, and may be, for example, soda-lime glass (blue sheet glass) with a thickness of about 1 mm to 3 mm.

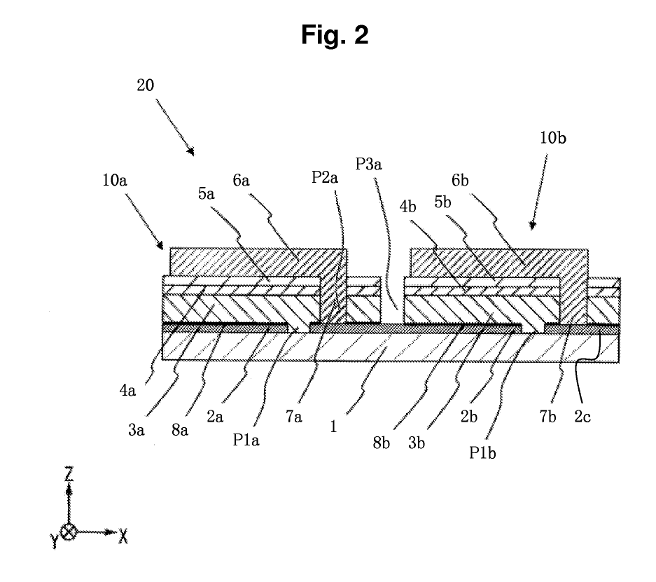

The lower electrode layers 2 are arranged on a principal surface of the substrate 1 in a single direction (the X-direction in FIGS. 1 and 2) with spaces therebetween. In this embodiment, three of the lower electrode layers 2 are separated from each other by separation grooves P1 corresponding to the above spaces. The lower electrode layers 2 contain molybdenum (Mo) or a molybdenum-containing alloy. Such lower electrode layers 2 are formed on the substrate 1 by a sputtering method, a vapor deposition method, or the like. The lower electrode layers 2 have a thickness of, for example, 0.2 μm to 1 μm.

The light-absorbing layers 3 are provided on the lower electrode layers 2. Each of the light-absorbing layers 3 is formed so as to extend from the lower electrode layer 2 of a corresponding one of the photoelectric conversion cells 10 to the lower electrode layer 2 of another corresponding one of the photoelectric conversion cells 10. The light-absorbing layers 3 are made of a compound semiconductor containing a Group I-B element (also referred to as a group 11 element) and a Group III-B element (also referred to as a group 13 element). In addition, the light-absorbing layers 3 further contain at least one of sulfur and selenium. Such a compound semiconductor contained in the light-absorbing layers 3 has a chalcopyrite structure and is also referred to as a chalcopyrite compound semiconductor (also referred to as a CIS compound semiconductor).

The chalcopyrite compound semiconductor may be, for example, copper indium diselenide (CuInSe₂), copper gallium diselenide (CuGaSe₂), copper indium/gallium diselenide (Cu(In, Ga)Se₂), copper indium disulfide (CuInS₂), copper gallium disulfide (CuGaS₂), copper indium/gallium disulfide (Cu(In, Ga)S₂), or copper indium/gallium diselenide/disulfide (Cu(In, Ga)(Se, S)₂). The chalcopyrite compound semiconductor may be a multinary compound semiconductor thin-film, made of copper indium/gallium diselenide or the like, including a copper indium/gallium diselenide/disulfide layer as a surface layer. In addition, the chalcopyrite compound semiconductor may be AgInSe₂, AgGaSe₂, or the like, in which the above Cu is replaced with silver (Ag). Furthermore, the chalcopyrite compound semiconductor may be CuAlSe₂, AgAlSe₂, or CuAlS₂, in which In or Ga is replaced with aluminum (Al). The light-absorbing layers 3 are, for example, thin films that have p-conductivity type and a thickness of about 1 μm to 3 μm. The light-absorbing layers 3 are principally composed of crystalline layers. The light-absorbing layers 3 may each partly include 8% by volume or less of an amorphous portion. The crystalline layers of the light-absorbing layers 3 can be confirmed by observation with a transmission electron microscope.

The buffer layers 4 are semiconductor layers that are each provided on a positive Z-side principal surface (also referred to as a one principal surface) of a corresponding one of the light-absorbing layers 3. The semiconductor layers have a second conductivity type (for example, an n-conductivity type) that is different from the second conductivity type of the light-absorbing layers 3. The buffer layers 4 are arranged in such a state that the buffer layers 4 are hetero-joined to the light-absorbing layers 3, which are made of the chalcopyrite compound semiconductor. In the photoelectric conversion cells 10, photoelectric conversion occurs in the light-absorbing layers 3 and buffer layers 4, which form heterojunctions. Therefore, the light-absorbing layers 3 and the buffer layers 4 function as photoelectric conversion layers.

The term “semiconductors different in conductivity type from each other” refers to semiconductors having different conductive carriers (carriers). The conductivity type of the light-absorbing layers 3 may be an n-type and the conductivity type of the buffer layers 4 may be a p-type.

The buffer layers 4 contain, for example, a compound semiconductor such as cadmium sulfide (CdS), indium sulfide (In₂S₃), zinc sulfide (ZnS), zinc oxide (ZnO), indium selenide (In₂Se₃), In(OH, S), (Zn, In)(Se, OH), or (Zn, Mg)O. The buffer layers 4 may have a resistivity of 1 Ω·cm or higher. This reduces a leakage current. The buffer layers 4 can be formed by, for example, a chemical bath deposition (CBD) method, or the like.

The buffer layers 4 have a thickness in a direction normal to a principal surface (positive Z-side) of each light-absorbing layer 3. The thickness of each buffer layer 4 may be 10 nm to 200 nm. When the thickness of the buffer layer 4 is 100 nm to 200 nm, the damage caused during the formation of the upper electrode layers 5 can be reduced.

Each upper electrode layer 5 is provided on a positive Z-side principal surface (also referred to as a principal surface) of a buffer layers 4. The upper electrode layers 5 have a role as a conductive film (also referred to as a transparent conductive film) which has an n-conductivity type and which is transparent. The upper electrode layers 5 are electrodes (also referred to as extraction electrodes) for extracting charges generated in the photoelectric conversion layers. In addition, the upper electrode layers 5 may have a resistivity less than that of the buffer layers 4. This allows the upper electrode layers 5 to have a reduced resistivity. The upper electrode layers 5 each may include a so-called window layer. The upper electrode layers 5 have a configuration in which the transparent conductive film is provided on the window layer.

The upper electrode layers 5 may be a low-resistivity substance which has a wide forbidden band and which is transparent. Such a substance is composed of, for example, zinc oxide (ZnO) or a zinc oxide compound (containing any one of aluminum (Al), boron (B), gallium (Ga), indium (In), and fluorine (F)). In addition, the upper electrode layers 5 may be composed of one containing at least one of, for example, indium oxide (ITO) containing tin (Sn) and tin oxide (SnO₂).

The upper electrode layers 5 are formed by, for example, a sputtering method, a vapor deposition method, a chemical vapor deposition (CVD) method, or the like so as to have a thickness of 0.05 μm to 3 μm. The upper electrode layers 5 have a resistivity of, for example, less than 1 Ω·cm and a sheet resistance of 50 Ω/square or less. This allows charges to be readily extracted from the photoelectric conversion layers.

The buffer layers 4 and the upper electrode layers 5 may have the property (also referred to as light transmissivity) of readily transmitting light with respect to wavelengths of light absorbed by the light-absorbing layers 3. Due to this, the reduction in light absorption efficiency of the light-absorbing layers 3 is reduced.

The upper electrode layers 5 may have a thickness of, for example, 0.05 μm to 0.5 μm. Due to this, light transmissivity is increased and a current is readily transmitted. When the upper electrode layers 5 and the buffer layers 4 have substantially the same absolute refractive index, the reflection of light at interfaces between the upper electrode layers 5 and the buffer layers 4 can be reduced.

The current-collecting electrodes 6 may be provided on the upper electrode layers 5. As shown in FIG. 1 or 2, the current-collecting electrodes 6 linearly extend from one end of the photoelectric conversion cell 10 to the connection conductors 7. The current-collecting electrodes 6 have a role in collecting charges generated in the photoelectric conversion layers through the upper electrode layers 5. Then, the collected charges are transmitted to the neighboring photoelectric conversion cell 10 through the connection conductors 7. Thus, in this embodiment, charges generated in the light-absorbing layers 3 can be efficiently extracted even if the upper electrode layers 5 are thin. Therefore, the current-collecting electrodes 6 contribute to the enhancement of power generation efficiency.

The current-collecting electrodes 6 may have a width of, for example, 50 μm to 400 μm. Due to this, the blocking of light incident on the light-absorbing layers 3 is reduced and the conductivity thereof can be maintained. The current-collecting electrodes 6 may each include a plurality of branched portions that is branched. The current-collecting electrodes 6 can be formed by, for example, printing in a pattern a metal paste containing a resin binder and a metal powder, such as an Ag powder, dispersed therein and then making it solidified.

The connection conductors 7 extend through the light-absorbing layers 3 and the buffer layers 4, and in the neighboring photoelectric conversion cells, each of the connection conductors 7 electrically connects the upper electrode layer 5 of a one of the photoelectric conversion cells 10 to the lower electrode layer 2 of another of the photoelectric conversion cells 10. The connection conductors 7 may be made of the same material as that for the upper electrode layers 5 or may be those formed by solidifying a metal paste. The term “solidification” includes a solid state after melting when a binder used in the metal paste is a thermoplastic resin. The term “solidification” also includes a state after curing when the binder is a heat-curable or photocurable resin. The metal paste may be one prepared by dispersing a metal powder such as an Ag powder in a resin binder, or the like. Due to this, the reliability of connections is increased.

Then, in this embodiment, intermediate layers 8 are arranged on the lower electrode layers 2. In other words, the intermediate layers 8 are interposed between the lower electrode layers 2 and the light-absorbing layers 3. The intermediate layers 8 each includes a compound layer containing at least one of sulfur and selenium, which are contained in the light-absorbing layers 3, and molybdenum. Furthermore, the compound layer includes an amorphous layer having no specific crystal structure. In this manner, unlike a MoSe₂ layer having crystal grown in a single direction perpendicular to a surface of each lower electrode layer 2, the intermediate layer 8 includes the amorphous layer, of which crystal axes are not fixed. In a conventional crystalline MoSe₂ layer, delamination is likely to occur at a cleavage plane or glide plane in a crystal. In contrast, since the amorphous layer, which is included in the intermediate layers 8, has no specific crystal structure, the occurrence of delamination at the cleavage plane or the glide plane as described can be reduced. Due to this, the delamination of the light-absorbing layers 3 caused by the division of the intermediate layers 8.

The intermediate layers 8 may include, for example, 15 to 60 mole % of molybdenum and 10 to 60 mole % of selenium. Furthermore, the intermediate layers 8 may include the Group I-B element and Group III-B element that are contained in the light-absorbing layers 3, in addition to molybdenum and at least one element of sulfur and selenium. Due to this, the composition of the intermediate layers 8 is close to that of the light-absorbing layers 3. Therefore, in such intermediate layers 8, the difference in thermal expansion coefficient, the lattice strain induced therein, or the like, which occur with the light-absorbing layers 3 can be reduced; hence, the light-absorbing layers 3 is more unlikely to be delaminated. At this time, when the intermediate layers 8 include 3 to 15 mole % of copper as a Group I-B element, 2 to 10 mole % of gallium as a Group III-B element, and 2 to 12 mole % of indium as a Group III-B element, it is possible to make lower resistance than that of MoSe₂. In such intermediate layers 8, the conversion efficiency of the photoelectric conversion device 20 is increased.

The proportion of elements in the intermediate layer 8 can be calculated by using, for example, energy dispersive X-ray spectroscopy (EDS: Energy Dispersive X-ray Spectroscopy). The fact that the intermediate layers 8 include the amorphous layers can be identified in such a manner that the intermediate layers 8 are observed with, for example, a transmission electron microscope and amorphousness is confirmed from the fact that substantially no crystal lattice fringes are present. Therefore, boundaries (interfaces) between the light-absorbing layers 3, which are principally composed of the crystalline layers, and the intermediate layers 8 can be readily confirmed with, for example, a transmission electron microscope. Furthermore, the intermediate layers 8 preferably have a thickness of about 10 nm to 50 nm from the viewpoint of reducing the stress due to volume expansion and shrinkage. Each intermediate layer 8 may partly include a crystalline portion. In this case, the crystalline portion is preferably 10% by volume or less of the intermediate layer 8.

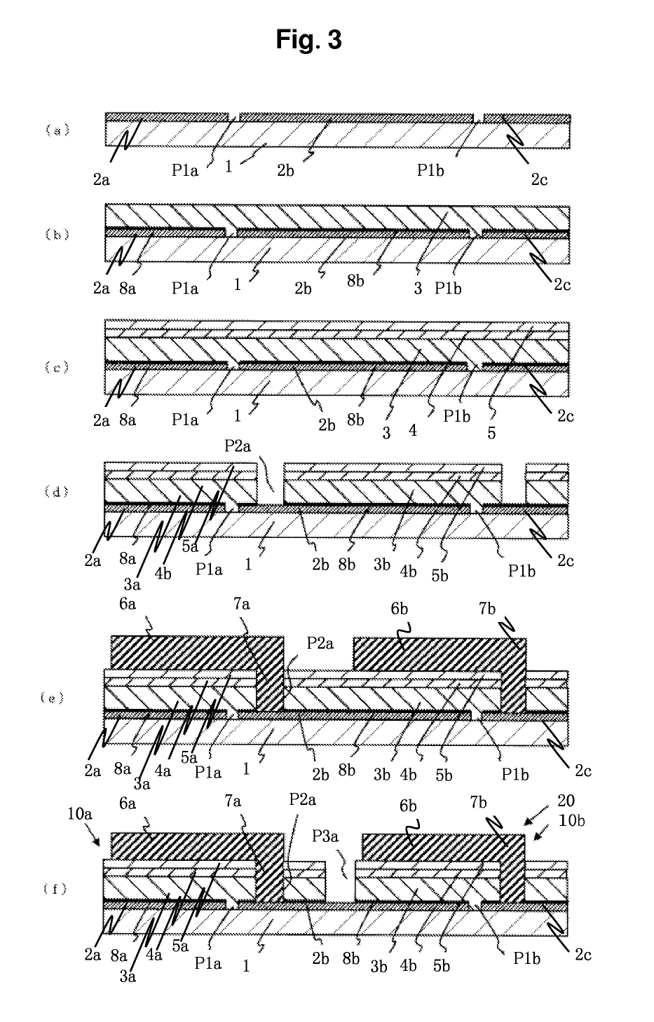

An example of a method of manufacturing the photoelectric conversion device 20 is described below with reference to FIG. 3.

The substrate 1 made from soda-lime glass or the like, is prepared. The substrate 1 has a size of, for example, about 50 cm×100 cm.

Next, the substrate 1 is cleaned. Then, as shown in FIG. 3(a), a molybdenum layer to be lower electrode layers 2 is formed on the principal surface of the substrate 1 by a sputtering method or the like so as to have a thickness of about 1 μm to 3 μm. The molybdenum layer is irradiated with a YAG (yttrium aluminum garnet) laser to form separation grooves P1. Due to this, the molybdenum layer is patterned, and a plurality of lower electrode layers 2 is formed. After the patterning, the molybdenum layer has a width of about 3 mm to 15 mm.

Then, as shown in FIG. 3(b), the light-absorbing layers 3 are formed on the lower electrode layers 2 by a sputtering method, a vapor deposition method, a printing method, or the like.

First, a method of preparing the light-absorbing layers by the sputtering method is described. After a metal thin-film containing Cu and Ga is formed on the lower electrode layers 2, which are formed on the substrate 1, by the sputtering method using, for example, a Cu—Ga alloy target, metal thin-films including In are deposited on the metal thin-film by the sputtering method using an In target, whereby a precursor layer is formed.

Next, the precursor layer is subsequently crystallized (selenized) with selenium. The substrate 1 on which the precursor layer is formed, and a box which is made of quartz and which contains a predetermined amount of selenium (Se) are provided in a furnace, and thereafter, pressure in the furnace is reduced and a reducing gas (for example, a hydrogen gas) is introduced into the furnace. After the concentration of oxygen in the furnace is reduced to about 500 ppm or less, heating the furnace is started. The concentration of oxygen in the furnace may be 100 ppm or less. In this case, the temperature in the furnace is maintained at about 400° C. to 600° C. for about 60 minutes to 90 minutes. Due to this, selenium in the box is evaporated to crystallize the precursor layer, whereby light-absorbing layers are formed. In this case, the concentration of hydrogen selenide in the furnace is maintained at about 30 ppm to 100 ppm by appropriately controlling the flow rate of the reducing gas and the like. By making the concentration of hydrogen selenide in the furnace low as described above, the crystallization of MoSe₂, which may possibly be formed on the lower electrode layers 2, is likely to be inhibited. Therefore, the intermediate layers 8 are amorphous layers containing molybdenum and selenium.

In the case where the intermediate layers 8 are caused to contain sulfur instead of selenium, sulfur may be used in the above preparation step instead of selenium. In the case where the intermediate layers 8 are caused to contain selenium and sulfur, after the intermediate layers 8 are formed in the above step so as to contain selenium, a sulfurization step of introducing sulfur vapor in an atmosphere heated to a temperature higher than the temperature at which selenium is introduced may be performed.

Next, a method of preparing the light-absorbing layers by the printing method is described. After a source solution containing selenium and the Group I-B and III-B elements contained in the light-absorbing layers 3 is applied to the lower electrode layers 2 that are located on the substrate 1, a precursor layer is formed by heat treatment at about 240° C. to 360° C. The above-mentioned source solution is applied onto this precursor layer again and is then heat-treated, whereby a plurality of precursor layers are formed. In this case, the concentration of selenium in a source solution used to form a precursor layer located on the lower electrode layer 2 side is set to be less than the concentration of selenium in a source solution used to form a precursor layer located opposite to the lower electrode layers 2. The ratio (Se/Group III-B element) of selenium to the Group III-B in the source solution used to form the precursor layer located on the lower electrode layer 2 side may be 0.05 to 0.2 less than the ratio (Se/Group III-B element) of selenium to the Group III-B in that used to form the precursor layer located uppermost opposite to the lower electrode layers 2.

Finally, the plurality of precursor layers layered are fired at about 470° C. to 600° C., whereby the intermediate layers 8 are formed and the light-absorbing layers 3 can be obtained. In this case, the concentration of selenium present on the lower electrode layer 2 side is small and therefore the crystallization of MoSe2 present at interfaces between the lower electrode layers 2 and the light-absorbing layers 3 is inhibited. Due to this, generation is reduced. The intermediate layers 8 can be formed so as to include amorphous layers containing molybdenum and selenium. In the case of forming the intermediate layers 8, which contain the Group I-B element and the Group III-B element, by the printing method, the amounts of the Group I-B and III-B elements contained in, for example, a source solution used first may be most. The above selenizing step may be performed after firing in order to compensate for selenium discharged from the light-absorbing layers 3 in the firing.

In the case where the intermediate layers 8 are caused to contain sulfur instead of selenium, sulfur may be used in the above-mentioned preparation step instead of selenium. In the case where the intermediate layers 8 are caused to contain selenium and sulfur, after the intermediate layers 8 are formed in the above step so as to contain selenium, a sulfurization step of introducing sulfur vapor may be performed in an atmosphere heated to a temperature higher than the temperature at which selenium is introduced.

In this manner, the intermediate layers 8, which include the amorphous layers, can be obtained by reducing the content of sulfur or selenium in the lower precursor layer, which is located near the lower electrode layers 2, for the light-absorbing layers 3. When a large amount of sulfur or selenium is present in the lower layer portion, the reaction with molybdenum is excessively promoted to cause crystal growth and therefore a compound such as crystalline MoS₂, MoSe₂, or Mo(S, Se)₂ is likely to be formed. In contrast, when the concentration of sulfur or selenium in the precursor layer located near the lower electrode layers 2 is made low, the regular crystal growth of the above compound is inhibited. Due to this, the intermediate layers 8 tend to have an irregular crystal structure, resulting in that the intermediate layers 8 become amorphous.

Then, as shown in FIG. 3(c), buffer layers 4 are formed on the light-absorbing layers 3 by a CBD method or the like. Furthermore, upper electrode layers 5 are formed on the buffer layers 4 by a sputtering method, an MOCVD method, or the like.

Next, as shown in FIG. 3(d), the light-absorbing layers 3, the buffer layers 4, and the upper electrode layers 5 are patterned. This patterning is performed by forming separation grooves P2 by, for example, mechanical scribing. The separation grooves P2 are provided with, for example, about 0.1 mm to 1 mm spaced from the separation grooves P1, which are located in the lower electrode layers 2. The separation grooves P2 are formed so as to have a width of, for example, about 100 μm to 1,000 μm. The separation grooves P2, which have such a width, can be formed by continuously scribing several times using a scribing needle having a scribe width of about 40 μm to 50 μm with the pitch shifted.

In addition, the separation grooves P2 may be formed by scribing with a scribing needle having an increased width of the tip shape thereof to a predetermined size. Alternatively, the separation grooves P2 may be formed by scribing once to several times using two or more scribing needles that are fixed in such a state that the scribing needles abut against each other or are closely arranged.

Then, as shown in FIG. 3(e), current-collecting electrodes 6 and connection conductors 7 are formed by printing a silver paste for resistance reduction on the upper electrode layers 5 and in the separation grooves P2. The connection conductor 7 located in separation grooves P2 can electrically connect the upper electrode layer 5 of one of the neighboring photoelectric conversion cells 10 to the lower electrode layer 2 of the other of the neighboring photoelectric conversion cells 10.

Finally, as shown in FIG. 3(f), separation grooves P3 are formed by patterning the light-absorbing layers 3, the buffer layers 4, and the upper electrode layers 5 by mechanical scribing. Due to this, the photoelectric conversion device 20 is thereby formed so as to include the photoelectric conversion cells 10 connected in series.

After the separation grooves P2 and P3 are formed, the intermediate layers 8 may be left on the lower electrode layers 2, which become surfaces of the separation grooves P2 and P3, and alternatively, the intermediate layers 8 may be removed when the separation grooves are formed.

In addition, an example shown in FIG. 3(c), after the separation grooves P2 only are formed by mechanical scribing before the upper electrode layers 5 are formed, the upper electrode layers 5 may be formed. In this case, the upper electrode layers 5 are formed in the separation grooves P2 and may be used instead of the connection conductors 7. Furthermore, the buffer layers 4 and the upper electrode layers 5 are continuously formed like the example shown in FIG. 3(c) and thereafter the separation grooves P2 may be formed. Due to this, the upper electrode layers 5 are formed in such a state that the buffer layers 4 are in good condition, whereby electrical connections between the buffer layers 4 and the upper electrode layers 5 can be maintained well. As a result, photoelectric conversion efficiency is increased. According to this way, contamination caused on surfaces of the buffer layers 4 by chippings generated by mechanical scribing can be reduced.

In this manner, the photoelectric conversion cells 10, which are unit cells having a structure in which the substrate 1, the lower electrode layers 2, the light-absorbing layers 3, the buffer layers 4, and the upper electrode layers 5 are laminated in this order from the back surface side. The photoelectric conversion device 20 has a structure in which the photoelectric conversion cells 10 are integrated by electrically connecting the plurality of photoelectric conversion cells 10 to each other.

The present invention is not limited to the above embodiments. Various modifications may be made without departing from the scope of the present invention.

The intermediate layers 8 may contain, for example, sodium. In this manner, when the intermediate layers 8 contain sodium, the hole concentration of the intermediate layers 8 can be increased. Due to this, since the ohmic contact between the lower electrode layers 2 and the light-absorbing layers 3 is maintained well, photoelectric conversion efficiency can be increased in such the intermediate layers 8. In this case, the concentration of sodium in the intermediate layers 8 may be about 1 to 10 mole %.

Such intermediate layers 8 containing sodium are formed, when the lower electrode layers 2, which contain molybdenum, are formed on the substrate 1, which contain soda-lime glass, by a sputtering method, by increasing the pressure during the forming the layers to about 0.8 Pa to 5 Pa. Defects or cavities in the lower electrode layers 2 are increased and the density of a film is reduced by increasing the pressure during the forming the layers. Due to this, stress to the lower electrode layers 2 in a tensile direction is applied. In the lower electrode layers 2 in which such tensile stress is applied, the diffusion of a component, such as sodium, contained in the substrate 1, which is made of soda-lime glass to the lower electrode layers 2, is increased. As a result, in such a film-forming method, the content of sodium into the intermediate layers 8 can be enhanced and the concentration of sodium in the lower electrode layers 2 can be increased. The tensile stress and compression stress in the lower electrode layers 2 can be confirmed by, for example, X-ray residual stress analysis method.

In addition, the intermediate layers 8 may contain sulfur (S) as described above. According to the intermediate layers 8, if defects are present in portions of the light-absorbing layers 3 that are close to the intermediate layers 8, the defects can be filled with sulfur. Due to this, the diffusion length of minor carriers generated in the above portions is increased, and the occurrence of the recombination of carriers is reduced. Therefore, photoelectric conversion efficiency is increased. The concentration of sulfur in the intermediate layers 8 may be, for example, 1 to 20 mole %. In such intermediate layers 8 that contain sulfur, the sulfurization step may be added during the formation of the light-absorbing layers 3 as described above. In another way, for example, NaS may be applied to the lower electrode layers 2 before the light-absorbing layers 3 are formed. Alternatively, sulfur may be formed on the lower electrode layers 2 by a sputtering method or the like before the light-absorbing layers 3 are formed. In another way, in a printing method, a sulfur-containing material such as NaS may be mixed with the source solution.

Furthermore, the intermediate layers 8 may contain oxygen (O). According to such intermediate layers 8, if defects are present in portions of the light-absorbing layers 3 that are close to the intermediate layers 8, the defects can be filled with oxygen. Due to this, the diffusion length of minor carriers generated in the above portions is increased, and the occurrence of the recombination of carriers is reduced. Therefore, photoelectric conversion efficiency is increased. In this case, the concentration of oxygen in the intermediate layers 8 may be, for example, 1 to 30 mole %.

For the intermediate layers 8 that contain oxygen, when the lower electrode layers 2 are formed by a sputtering method, for example, about 3 to 15% of an oxygen gas (O₂) with respect to an argon gas may be added to an argon gas in a sputtering gas. Due to this, the concentration of oxygen in the lower electrode layers 2 is increased and the oxygen diffuses into the intermediate layers 8 during the formation (firing) of the intermediate layers 8.

Also, the molar concentration of oxygen in the intermediate layers 8 may be greater than the molar concentration of oxygen in the lower electrode layers 2 and the light-absorbing layers 3. Due to this, the intermediate layers 8 can have an increased oxygen concentration, whereby the proportion of sulfur or selenium combining with molybdenum can be reduced and the production of MoS₂, MoSe₂, Mo(S, Se)₂, or the like can be reduced. In this case, the molar concentration of oxygen in the intermediate layers 8 may be about 5 to 20 mole % greater than the molar concentration of oxygen in the lower electrode layers 2 and the light-absorbing layers 3.

Such intermediate layers 8 can be prepared by, for example, after the lower electrode layers 2 are formed, oxide films are formed on surfaces of the lower electrode layers 2 by heating at about 150° C. to 200° C. for five minutes to 15 minutes in air and are cleaned with pure water and the light-absorbing layers 3 are then formed.

The proportion of the molar concentration of gallium in the intermediate layers 8 in the sum of the molar concentrations of gallium and indium in the intermediate layers 8 may be greater than the proportion of the molar concentration of gallium in the light-absorbing layers 3 in the sum of the molar concentrations of gallium and indium in the light-absorbing layers 3. According to such intermediate layers 8, the band gap of the back side (non-light-incident side) of the light-absorbing layers 3 is large, a graded structure is formed, and the current generated from the photoelectric conversion device 20 can be increased. In this case, the proportion of the molar concentration of gallium in the intermediate layers 8 in the sum of the molar concentrations of gallium and indium in the intermediate layers 8 is about 30 to 60% and may be about 10 to 35% greater than the proportion of the molar concentration of gallium in the light-absorbing layers 3 in the sum of the molar concentrations of gallium and indium in the light-absorbing layers 3.

For the intermediate layers 8, for example, the concentration of gallium in the source solution that is applied to the lower electrode layers 2 when the light-absorbing layers 3 are formed may be increased. That is, the source solution may be prepared such that the concentration of gallium in a precursor layer provided on the lower electrode layer 2 side is greater than the concentration of gallium in a precursor layer provided on the buffer layer 4 side. On the other hand, for the intermediate layers 8, the concentration of indium in the source solution that is applied to the lower electrode layers 2 when the light-absorbing layers 3 are formed may be reduced when the light-absorbing layers 3 are formed. That is, the source solution may be prepared such that the concentration of indium in the precursor layer provided on the lower electrode layer 2 side is less than the concentration of indium in the precursor layer provided on the buffer layer 4 side.

The molar concentration of oxygen, gallium or indium in the lower electrode layers 2, the light-absorbing layers 3, and the intermediate layers 8 can be measured by, for example, energy dispersive X-ray spectroscopy (EDS) in such a manner that a cross section is observed with an electron microscope; may be measured by X-ray photoelectron spectroscopy (XPS) in such a manner that the light-absorbing layers 3 are scraped by a sputtering method in a thickness direction, or may be measured by Auger electron spectroscopy (AES).

When surface layers of the lower electrode layers 2 that are in contact with the intermediate layers 8 are made of molybdenum, the orientation of the surface layers thereof may be (110) plane. A molybdenum crystal usually has a body-centered cubic structure. Therefore, the (110) plane of the molybdenum crystal has larger surface atom density as compared to the (100) plane and the (111) plane. Due to this, when the orientation of the surface layers of the lower electrode layers 2 is the (110) plane, sulfur atoms or selenium atoms are unlikely to migrate into the surface layers of the lower electrode layers 2 from the light-absorbing layers 3. As a result, a compound such as MoS₂, MoSe₂, Mo(S, Se)₂, or the like is unlikely to have crystal growth and therefore is likely to be amorphous.

The lower electrode layers 2, which have the surface layers having the (110) plane, are obtained by, for example, reducing the deposition temperature of molybdenum and by increasing the deposition pressure. For deposition conditions, for example, a deposition temperature may be 20 to 150° C. and a deposition pressure may be 2 to 4 Pa. When the deposition rate is relatively low, for example, 0.6 nm/sec to 1.5 nm/sec, the surface layers are more likely to be oriented in the (110) plane. The surface layers of the lower electrode layers 2 may contain about 1 mole % or less of an impurity, such as a metal component, a glass component, or the like, other than molybdenum.

### REFERENCE SIGNS LIST

1 Substrate
2 Lower electrode layers (electrode layers)
3 Light-absorbing layers
4 Buffer layers
5 Upper electrode
6 Current-collecting electrodes
7 Connection conductors
8 Intermediate layers
10 Photoelectric conversion cells
20 Photoelectric conversion device
P1 to P3 Separation grooves

1. A photoelectric conversion device comprising:
an electrode layer comprising molybdenum;
an intermediate layer formed on the electrode layer; and
a light-absorbing layer formed on the intermediate layer, and comprising:
one or more Group I-B elements;
one or more Group III-B elements; and
at least one element of sulfur and selenium
wherein the intermediate layer comprises an amorphous layer comprising at least one of the sulfur and the selenium which are contained in the light-absorbing layer, and molybdenum.

2. The photoelectric conversion device according to claim 1, wherein the intermediate layer further contains one or more Group I-B elements and one or more Group III-B elements.

3. The photoelectric conversion device according to claim 1, wherein the intermediate layer further contains sodium.

4. The photoelectric conversion device according to claim 1, wherein the intermediate layer further contains oxygen.

5. The photoelectric conversion device according to claim 4, wherein the electrode layer and the light-absorbing layer further contain oxygen and the molar concentration of oxygen in the intermediate layer is greater than the molar concentration of oxygen in the electrode layer and the light-absorbing layer.

6. The photoelectric conversion device according to claim 1, wherein the light-absorbing layer and the intermediate layer contain gallium and indium and the proportion of the molar concentration of gallium in the intermediate layer in the sum of the molar concentrations of gallium and indium in the intermediate layer is greater than the proportion of the molar concentration of gallium in the light-absorbing layer in the sum of the molar concentrations of gallium and indium in the light-absorbing layer.

7. The photoelectric conversion device according to claim 1, wherein
the electrode layer further comprises a surface layer,
the surface layer is in contact with the intermediate layer and comprises molybdenum, and
the orientation of the surface layer is along the (110) plane.

8. The photoelectric conversion device according to claim 1, wherein the electrode layer directly coupled to the amorphous layer.

9. A photoelectric conversion device comprising:
an first layer comprising molybdenum;
an second layer on the first layer, comprising amorphous portion, the amorphous portion comprising:
molybdenum; and
one or more elements selected from a group consisting of sulfur and selenium; and
a third layer formed on the second layer, and comprising:
a Group I-B element;
a Group III-B element; and
one or more elements selected from a group consisting of sulfur and selenium.
